(19) United States
(12) Patent Application Publication
(10) Pub. No.: US 2024/0023264 A1
(43) Pub. Date: Jan. 18, 2024

(54) FUNCTIONAL ASSEMBLY AND MULTI-FUNCTIONAL DISPLAY DEVICE

(71) Applicant: Qisda Corporation, Taoyuan City (TW)

(72) Inventors: Yi-Ching LIN, Taoyuan City (TW); Hung-Hsun LIU, Taoyuan City (TW)

(73) Assignee: Qisda Corporation, Taoyuan City (TW)

(21) Appl. No.: 18/202,992

(22) Filed: May 29, 2023

(30) Foreign Application Priority Data
Jul. 18, 2022 (CN) 202210839408.2

(51) Int. Cl. H05K 7/14; H02J 7/00

(52) U.S. Cl. CPC H05K 7/14; H02J 7/0044

(57) ABSTRACT

A functional assembly disposed on a display device is provided. The display device has a display surface. The functional assembly includes a first bracket disposed on a back surface of the display device, a second bracket pivotally connected to the one end of the first bracket and rotatable with respect to the first rotation shaft, and a base pivotally connected to the one end of the second bracket and rotatable with respect to the second rotation shaft. One end of the first bracket has a first rotation shaft. One end of the second bracket has a second rotation shaft. One of the first and second rotation shafts is perpendicular to the display surface, and the other one is parallel to the display surface. The base can be shielded from the back surface of the display device and can be exposed on the one side of the display device.

This application claims the benefit of People's Republic of China application Serial No. 202210839408.2, filed Jul. 18, 2022, the subject matter of which is incorporated herein by reference.

### BACKGROUND OF THE INVENTION

### Field of the Invention

The invention relates in general to a functional assembly and a multi-functional display device.

### Description of the Related Art

Apart from providing the display function, the display device can have an assembly disposed on the peripheral to enhance the function of the display. The assembly can be a hanging rack or a base. When the assembly is a hanging rack, relevant computer peripherals can be hanged on the hanging rack. When the assembly is a base, an object can be placed on the base fixed on one side of a display device. However, due to the limited space, assembly with a large volume cannot be received therein. The conventional assembly cannot provide both practicality and convenience due to its simple structure, insufficient supporting force, and non-adjustable angle. Therefore, it has become a prominent task to enhance the supporting force of the miniaturized structure of the assembly and further make the angle of the assembly adjustable.

### SUMMARY OF THE INVENTION

The present invention is directed to a functional assembly and a multi-functional display device, wherein the functional assembly can be exposed on one side of the display device, so that the user can conveniently adjust the angle and orientation of the functional assembly.

According to one embodiment of the present invention, a functional assembly disposed on a display device is provided. The display device has a display surface. The functional assembly includes a first bracket, a second bracket and a base. The first bracket is disposed on a back surface of the display device and is extended from one side of the display device towards a first extension direction. One end of the first bracket has a first rotation shaft. The second bracket is pivotally connected to the one end of the first bracket and rotatable with respect to the first rotation shaft. One end of the second bracket has a second rotation shaft. One of the first rotation shaft and the second rotation shaft is perpendicular to the display surface of the display device, and the other one of the first rotation shaft and the second rotation shaft is parallel to the display surface of the display device. The base is pivotally connected to the one end of the second bracket and is rotatable with respect to the second rotation shaft. The base can be shielded from the back surface of the display device. When the base is exposed on the one side of the display device, a placing surface of the base and the display surface both face a front surface of the display device.

According to another embodiment of the present invention, a multi-functional display device is provided. The multi-functional display device includes a display device and an assembly, The display device has a display surface. The assembly includes a first bracket, a second bracket and a base. The first bracket is disposed on a back surface of the display device and is extended from one side of the display device towards a first extension direction. One end of the first bracket has a first rotation shaft. The second bracket is pivotally connected to the one end of the first bracket and rotatable with respect to the first rotation shaft. One end of the second bracket has a second rotation shaft. One of the first rotation shaft and the second rotation shaft is perpendicular to the display surface of the display device, and the other one of the first rotation shaft and the second rotation shaft is parallel to the display surface of the display device. The base is pivotally connected to the one end of the second bracket and is rotatable with respect to the second rotation shaft. The base can be shielded from the back surface of the display device. When the base is exposed on the one side of the display device, a placing surface of the base and the display surface both face a front surface of the display device.

The functional assembly of the present invention has several rotation shafts and a base. Two brackets can rotate with respect to the rotation shafts respectively to be positioned on one side of the display device, so that the user can conveniently adjust the angle and orientation of the functional assembly for an object to be placed on the base. Thus, the functional assembly of the present invention possesses both practicality and variability.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a display device with a functional assembly according to an embodiment of the present invention.

FIGS. 2A to 2D respectively are schematic diagrams of the operations of a functional assembly according to an embodiment of the present invention.

FIG. 3 is a perspective of the functional assembly of FIG. 2A.

FIG. 4A is a schematic diagram of a first limiting structure according to an embodiment of the present invention.

FIG. 4B is a schematic diagram of a second limiting structure according to an embodiment of the present invention.

FIG. 4C is a schematic diagram of a third limiting structure according to an embodiment of the present invention.

FIGS. 5A and 5B respectively are bottom views of a functional assembly according to an embodiment of the present invention.

FIG. 6 is a schematic diagram of a clamping structure according to an embodiment of the present invention.

### DETAILED DESCRIPTION OF THE INVENTION

Detailed descriptions of the invention are disclosed below with a number of embodiments. However, the disclosed embodiments are for explanatory and exemplary purposes only, not for limiting the scope of protection of the invention.

Details of the exemplary embodiments are described below with reference to accompanying drawings. The exemplary embodiments can be implemented in many ways, and are not limited to the exemplifications. Conversely, the exemplary embodiments make the present application more completely and comprehensively understood and the concepts fully exposed to anyone ordinarily skilled in the technology field of the present application. Technical features, structures or characteristics disclosed in the present application can be suitable combined in one or more than one exemplary embodiment.

Besides, the accompanying drawings only illustrate the features of the present invention and are not necessarily based on actual sizes and scales. Similar/identical designations are used to indicate similar/identical elements, and similar/identical descriptions are not repeated.

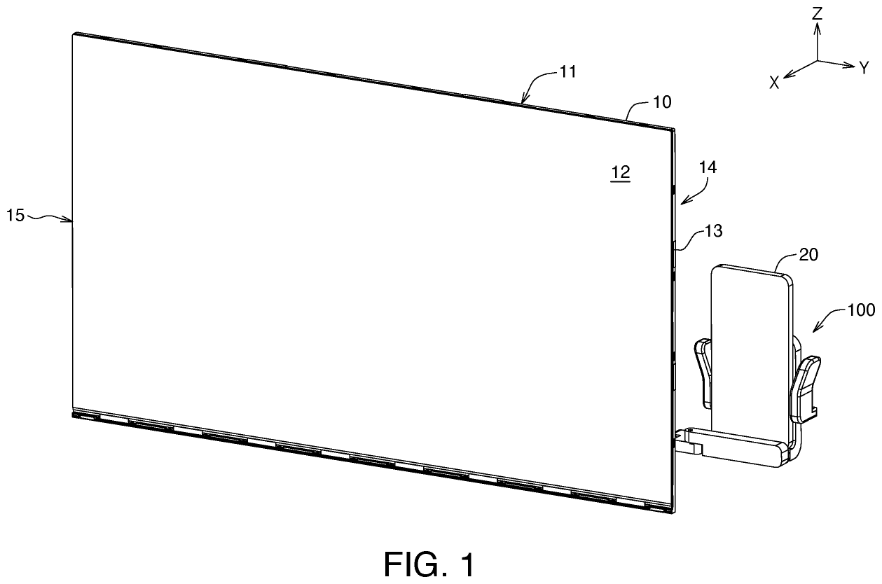

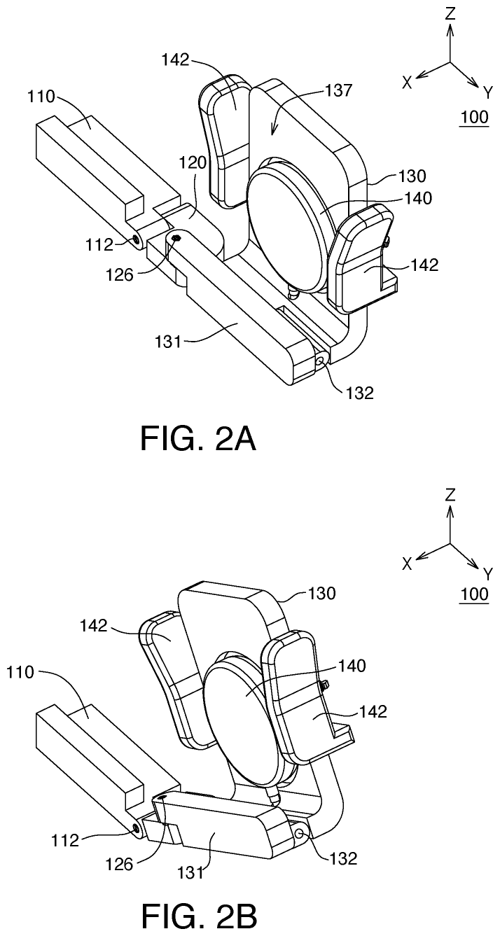

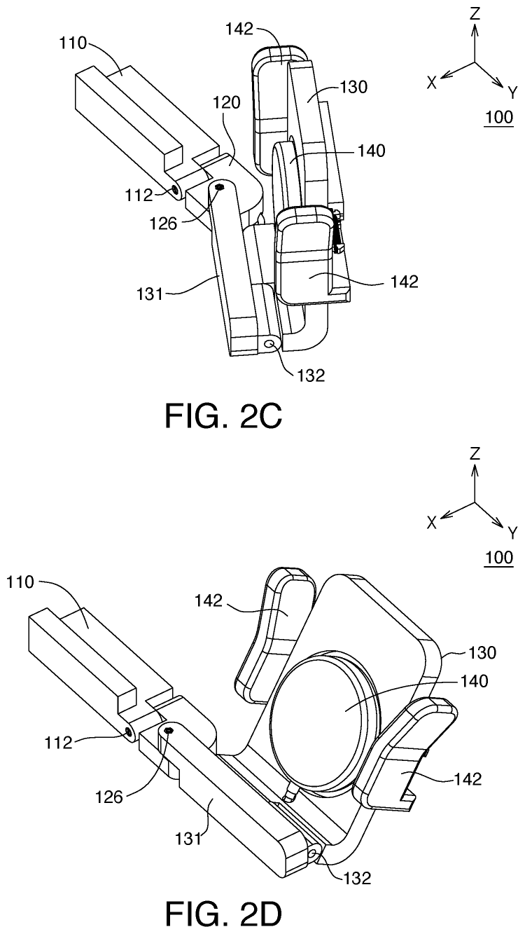

Refer to FIG. 1 and FIGS. 2A to 2D. FIG. 1 is a schematic diagram of a display device 10 with a functional assembly 100 according to an embodiment of the present invention. FIGS. 2A to 2D respectively are schematic diagrams of the operations of a functional assembly 100 according to an embodiment of the present invention.

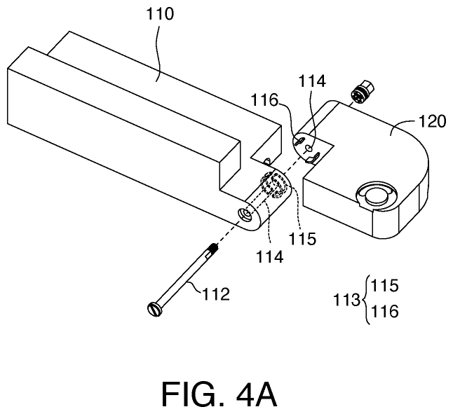

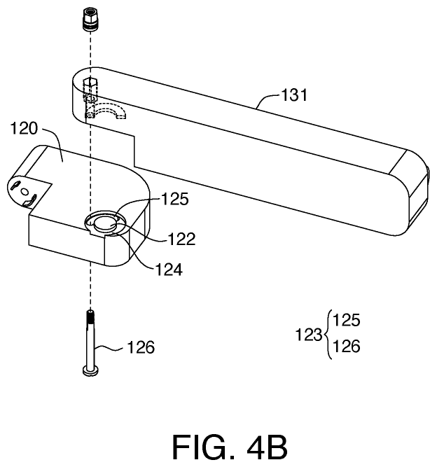

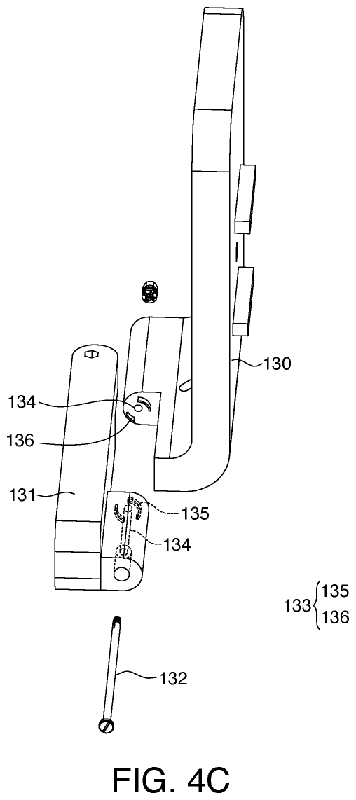

The functional assembly 100 is disposed on a display device 10. The display device 10 has a display surface 12. The functional assembly 100 includes a first bracket 110, a second bracket 120 and a base 130. The first bracket 110 is disposed on a back surface 14 of the display device 10. The first bracket 110 is extended from one side 13 of the display device 10 towards a first extension direction, and one end of the first bracket 110 has a first rotation shaft 112. The second bracket 120 is pivotally connected to one end of the first bracket 110 and is rotatable with respect to the first rotation shaft 112, and one end of the second bracket 120 has a second rotation shaft 122 (referring to FIG. 4B). One of the first rotation shaft 112 and the second rotation shaft 122 is perpendicular to the display surface 12 of the display device 10, and the other one of the first rotation shaft 112 and the second rotation shaft 122 is parallel to the display surface 12 of the display device 10. The base 130 is pivotally connected to one end of the second bracket 120 and is rotatable with respect to the second rotation shaft 122. The base 130 can be shielded from the back surface 14 of the display device 10. When the base 130 is exposed on one side 13 of the display device 10, a placing surface 137 of the base 130 and the display surface 12 both face a front surface (that is, the front) of the display device 10.

Refer to FIG. 1. The first bracket 110 is disposed on the back surface 14 of the display device 10 and is adjacent to one side 13 of the display device 10 (such as the left side or the right side). The first bracket 110 can be extended from one side 13 of the display device 10 towards the first extension direction (such as a horizontal extension direction or a vertical extension direction). The first extension direction can be the direction of the long edge 11 or the short edge 15 of the display device 10. As indicated in FIG. 1, when the display device 10 is in a horizontal display mode, the first extension direction can be parallel to the long edge 11 of the display device 10. In another embodiment, when the display device 10 is in a vertical display mode, the first extension direction can be parallel to the short edge 15 of the display device 10. The present invention does not impose specific restrictions regarding the said arrangement.

Refer to FIG. 2A. The first bracket 110 can be a long strip fixed on the back surface 14 of the display device 10 or slidably disposed on the back surface 14 of the display device 10. The design of a slidable first bracket 110 enables the first bracket 110 to move along the first extension direction (such as the Y axis) and be exposed from one side 13 of the display device 10, so that the first bracket 110 can move along the first extension direction (such as the Y axis) to be shielded from the back surface 14 of the display device 10.

Refer to FIG. 2A and FIG. 2B. One end of the first bracket 110 (such as the outer end) has a first rotation shaft 112, and the second bracket 120 is pivotally connected to the outer end of the first bracket 110 and is rotatable with respect to the first rotation shaft 112. That is, the second bracket 120 can rotate with respect to the first bracket 110. The first rotation shaft 112 is perpendicular to the display surface 12 of the display device 10, so that the rotation angle of the second bracket 120 can be adjusted with respect to a specific axial direction (the X axis) according to actual needs; or the first rotation shaft 112 is parallel to the display surface 12 of the display device 10, so that the rotation angle of the second bracket 120 can be adjusted with respect to a specific axial direction (the Z axis or the Y axis) according to actual needs.

Refer to FIG. 2B and FIG. 2C. One end of the second bracket 120 has a second rotation shaft 122 (referring to FIG. 4B). The second rotation shaft 122 and the first rotation shaft 112 are not on the same axis. That is, when the first rotation shaft 112 is disposed on the axis (the X axis) perpendicular to the display surface 12 of the display device 10, the second rotation shaft 122 is disposed on the axis parallel to the display surface 12 of the display device 10 (the Z axis or the Y axis). In another embodiment, when the first rotation shaft 112 is disposed on the axis (the Z axis or the Y axis) parallel to the display surface 12 of the display device 10, the second rotation shaft 122 is disposed on the axis (the X axis) perpendicular to the display surface 12 of the display device 10. With the first rotation shaft 112 and the second rotation shaft 122 being orthogonal to each other, the rotation angle of the base 130 can be adjusted on two corresponding axes.

Refer to FIGS. 2B to 2D. The base 130 is pivotally connected to one end of the second bracket 120 and is rotatable with respect to the second rotation shaft 122, so that the rotation angle of the base 130 can be adjusted with respect to the second bracket 120. Besides, the base 130 also can rotate with respect to the first rotation shaft 112, so that the angle of the base 130 can be adjusted with respect to the first bracket 110. In the present embodiment, when the base 130 rotates anti-clockwise by 90 degrees with respect to the first rotation shaft 112, the base 130 can be shielded from the back surface 14 of the display device 10 to avoid occupying the peripheral space of the display device 10. When the base 130 rotates clockwise by 90 degrees with respect to the first rotation shaft 112, the base 130 can be exposed on one side 13 of the display device 10 for an object (such as a wireless electronic device 20) to be placed thereon.

Refer to FIG. 2D. The base 130 has a third bracket 131, for example, and one side of the third bracket 131 has a third rotation shaft 132 extended from one end of the second bracket 120 towards a second extension direction. The second extension direction is parallel to the first extension direction or tilts towards the first extension direction at an angle, so that the third bracket 131 can swing left and right with respect to the display surface 12.

As indicated in FIG. 2A, when the second extension direction is parallel to the first extension direction, the third bracket 131 and the first bracket 110 are located on the same axis (the Y axis). As indicated in FIG. 2C, when the second extension direction is not parallel to the first extension direction (such as tilts at an angle of 30 degrees), the third bracket 131 and the first bracket 110 are not located on the same axis (the Y axis), so that the rotation angle of the third bracket 131 can be adjusted with respect to one axis (the Z axis) according to actual needs.

Refer to FIG. 2D. The base 130 can be a charging dock. The charging dock includes a wireless charging pad 140 (or a wired charging dock, the diagram only illustrates one of the possible embodiments). The charging dock is pivotally connected to one side of the third bracket 131 and is rotatable with respect to the third rotation shaft 132. When the third rotation shaft 132 is parallel to the display surface 12 of the display device 10, the third rotation shaft 132 enables the wireless charging pad 140 to swing back and forth with respect to the display surface 12.

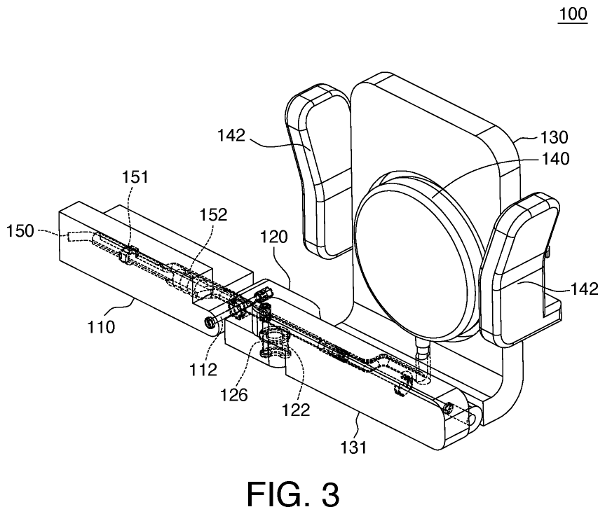

Refer to FIG. 3 and FIGS. 4A to 4C. FIG. 3 is a perspective of the functional assembly 100 of FIG. 2A. FIG. 4A is a schematic diagram of a first limiting structure 113 according to an embodiment of the present invention. FIG. 4B is a schematic diagram of a second limiting structure 123 according to an embodiment of the present invention. FIG. 4C is a schematic diagram of a third limiting structure 133 according to an embodiment of the present invention.

The first bracket 110 has a first shaft hole 114 and a first limiting structure 113. The first rotation shaft 112 is tightly engaged in the first shaft hole 114, and the rotation angle of the first rotation shaft 112 is limited by the first limiting structure 113 to be less than or equivalent to a pre-determined angle (such as less than or equivalent to 90 degrees).

Refer to FIG. 3 and FIG. 4A. The first rotation shaft 112 is tightly engaged in the first shaft hole 114, so that the second bracket 120, being tightly engaged, can rotate to be positioned on the first bracket 110. In an embodiment, when the second bracket 120 rotates clockwise to a horizontal position by 90 degrees and is substantially parallel to the first bracket 110, the second bracket 120 is positioned on the first bracket 110 through the first limiting structure 113, so that the second bracket 120 can bear the weights of the base 130 and the object disposed on the base 130. The first limiting structure 113 can be formed of a latch 116 and a card slot 115 or realized by other forms of slidable snap structure. The latch 116 can slide within the card slot 115, but the present invention does not impose specific restrictions regarding the said arrangement.

Also, the second bracket 120 has a second shaft hole 124 and a second limiting structure 123. The second rotation shaft 122 is tightly engaged in the second shaft hole 124, and the rotation angle of the second rotation shaft 122 is limited by the second limiting structure 123 to be less than or equivalent to a pre-determined angle (such as less than or equivalent to 90 degrees).

Refer to FIG. 3 and FIG. 4B. The second rotation shaft 122 is tightly engaged in the second shaft hole 124, so that the third bracket 131, being tightly engaged, can rotate to be positioned on the second bracket 120. In an embodiment, when the third bracket 131 rotates anti-clockwise by 90 degrees and is substantially parallel to the first bracket 110, the third bracket 131 is positioned on the second bracket 120 through the second limiting structure 123, so that the base 130 can be exposed on one side 13 of the display device along the X axis. Thus, the user can view the base 130 and the object (such as a wireless electronic device 20) on the base 130 from the front surface of the display device 10. The second limiting structure 123 can be formed of a latch 126 and a card slot 125 or realized by other types of slidable snap structure. The latch 126 can slide within the card slot 125, but the present invention does not impose specific restrictions regarding the said arrangement.

Furthermore, the third bracket 131 has a third shaft hole 134 and a third limiting structure 133. The third rotation shaft 132 is tightly engaged in the third shaft hole 134, and the rotation angle of the third rotation shaft 132 is limited by the third limiting structure 133 to be less than or equivalent to a pre-determined angle (such as less than or equivalent to 90 degrees).

Refer to FIG. 3 and FIG. 4C. The third rotation shaft 132 is tightly engaged in the third shaft hole 134, so that the wireless charging pad 140 of the base 130, being tightly engaged, can rotate to be positioned on the third bracket 131. In an embodiment, when the wireless charging pad 140 rotates anti-clockwise to a vertical position by 90 degrees and is substantially perpendicular to the third bracket 131, the wireless charging pad 140 is positioned on the third bracket 131 through the third limiting structure 133, so that the placing surface 137 of the base 130 substantially faces the front surface (that is, the front) of the display device 10. The third limiting structure 133 can be formed of a latch 136 and a card slot 135 or realized by other types of slidable snap structure. The latch 136 can slide within the card slot 135, but the present invention does not impose specific restrictions regarding the said arrangement.

Also, the functional assembly 100 can include a charging wire 150. One end 150a of the charging wire 150 is fixed and connected to the base 130. The other end 150b of the charging wire 150 is fixed and connected to the display device 10. The charging wire 150 has a winding portion 152, which can be stretched or contracted when the base 130 rotates with respect to the first rotation shaft 112 and/or the second rotation shaft 122.

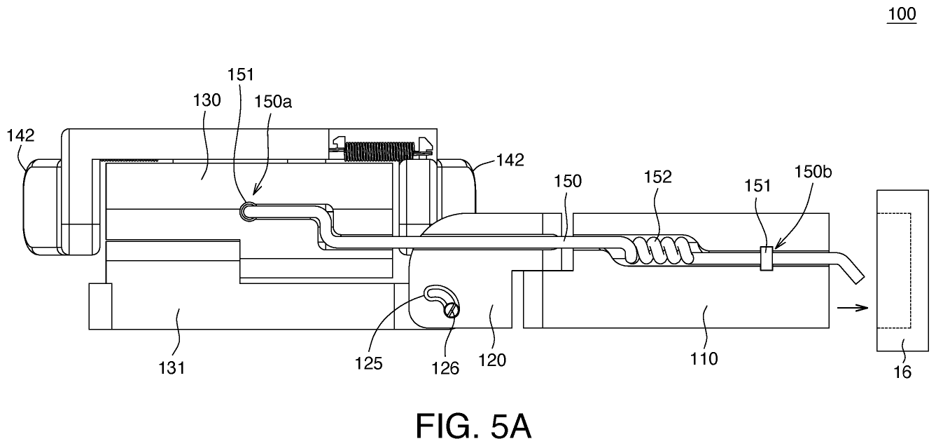

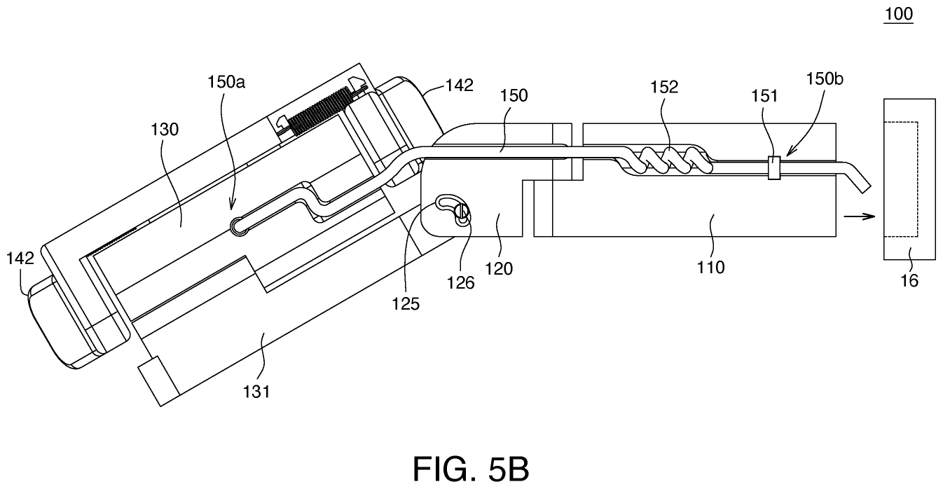

Referring to FIG. 5A and FIG. 5B, bottom views of a functional assembly 100 according to an embodiment of the present invention are shown. The charging wire 150 is extended to the bottom of the functional assembly 100. One end 150a of the charging wire 150 can pass through the base 130 and connect to the bottom of the wireless charging pad 140. The other end 150b of the charging wire 150 can be extended to the back surface 14 of the display device 10 (or can be extended to the inside of the display device 10). The fixing element 151 is fixed to the two ends of the charging wire 150, so that the two ends of the charging wire 150 will not be pulled off or come off when the functional assembly 100 rotates.

In the present embodiment, when the second bracket 120 rotates with respect to the first bracket 110 or when the third bracket 131 rotates with respect to the second bracket 120, the winding portion 152 of the charging wire 150 can provide extra wire, so that when the charging wire 150 is completely pulled straight, the two ends of the charging wire 150 still remain fixed and will not be pulled off or come off along with the rotation of the functional assembly 100.

Furthermore, the internal power (not illustrated) of the display device 10 can provide power to the wireless charging pad 140 via the charging wire 150; or one end of the charging wire 150 has a power plug (not illustrated in the diagram). The power plug can be electrified through a slot 16 disposed on the display device 10 to provide necessary power. In an embodiment as indicated in FIG. 5A and FIG. 5B, the back surface 14 of the display device 10 has a slot 16. The slot 16 faces one side 13 of the display device 10, the first bracket 110 can be pluggably installed in the slot 16. The slot 16 enables the functional assembly 100 to be fixed on the back surface 14 of the display device 10; or, the slot 16 has an electrification function. Thus, the charging wire 150 can be electrified through the slot 16 to provide necessary power to the wireless charging pad 140. The slot 16 can be a USB slot or other types of slot, and the present invention does not impose specific restrictions regarding the said arrangement.

The charging dock can further include a clamping device 141 disposed on two sides of the wireless charging pad 140. The clamping device 141 is used to clamp a wireless electronic device 20 disposed on the wireless charging pad 140.

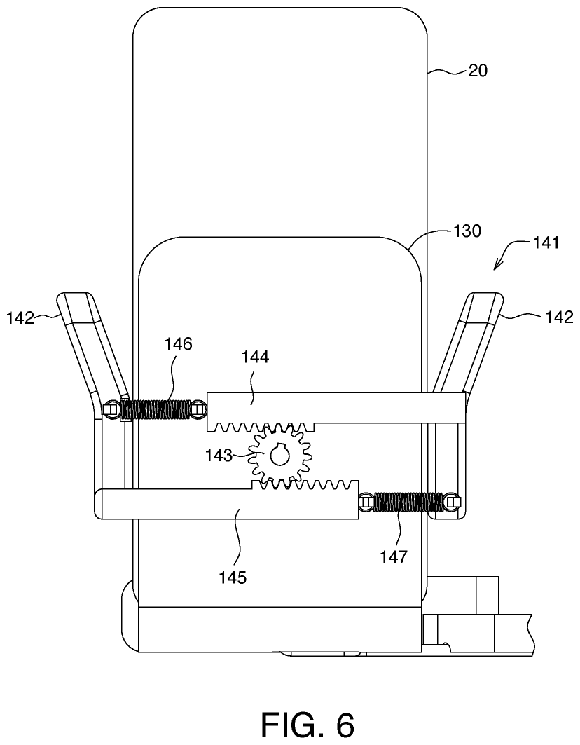

Refer to FIG. 6. The clamping device 141 includes two clampers 142, a transmission piece 143, two movable pieces 144 and 145 and two flexible telescopic pieces 146 and 147. The transmission piece 143 can be a driving gear; each of the two movable pieces 144 and 145 can be a rack engaged with the driving gear. Besides, the two flexible telescopic pieces 146 and 147 respectively are disposed between the two movable pieces 144 and 145 and the two clampers 142, and the two flexible telescopic pieces 146 and 147 are driven by the transmission piece 143 to be stretched outward or contracted inward to adjust the positions of the two clampers 142 and to clamp or release the wireless electronic device 20. The transmission piece 143 can be driven by a motor or other mechanic structures, and the present invention does not impose specific restrictions regarding the said arrangement.

According to the functional assembly and the display device with the functional assembly disclosed in above embodiments of the present invention, the functional assembly is positioned on one side of the display device, so that the user can conveniently adjust the angle and orientation of the functional assembly. Since the placing surface of the base and the display surface of the display device both face the same direction (such as the front surface of the display device), when the user is viewing the display surface, the peripheral vision of the user's eyes still can view the wireless electronic device placed on the base. When the wireless electronic device receives a message or a notice, the user can immediately sense it and will not miss important information. Also, the charging wire is tidily received in the functional assembly of the present embodiment, hence avoiding the problems of the wires being exposed and messy. Thus, the functional assembly of the present invention possesses both practicality and variability.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A functional assembly disposed on a display device, wherein the display device has a display surface, and the functional assembly comprises:
a first bracket disposed on a back surface of the display device, wherein the first bracket is extended from one side of the display device towards a first extension direction, and one end of the first bracket has a first rotation shaft;
a second bracket pivotally connected to the one end of the first bracket and rotatable with respect to the first rotation shaft, wherein one end of the second bracket has a second rotation shaft, one of the first rotation shaft and the second rotation shaft is perpendicular to the display surface of the display device, and the other one of the first rotation shaft and the second rotation shaft is parallel to the display surface of the display device; and
a base pivotally connected to the one end of the second bracket is rotatable with respect to the second rotation shaft, wherein the base is adapted to be shielded from the back surface of the display device, when the base is exposed on the one side of the display device, a placing surface of the base and the display surface both face a front surface of the display device.

2. The functional assembly according to claim 1, wherein the first bracket is fixed on the back surface of the display device or is slidably disposed on the back surface of the display device.

3. The functional assembly according to claim 1, wherein the back surface of the display device has a slot facing the one side of the display device, and the first bracket is pluggably installed in the slot.

4. The functional assembly according to claim 1, wherein the first bracket has a first shaft hole and a first limiting structure, the first rotation shaft is disposed in the first shaft hole, the first rotation shaft and the first shaft hole are tightly engaged and a rotation angle of the first rotation shaft is limited by the first limiting structure to be less than or equivalent to a pre-determined angle.

5. The functional assembly according to claim 1, wherein the second bracket has a second shaft hole and a second limiting structure, the second rotation shaft is disposed in the second shaft hole, the second rotation shaft and the second shaft hole are tightly engaged and a rotation angle of the second rotation shaft is limited by the second limiting structure to be less than or equivalent to a pre-determined angle.

6. The functional assembly according to claim 1, wherein the base has a third bracket, one side of the third bracket has a third rotation shaft extended from the one end of the second bracket towards a second extension direction, and the second extension direction is parallel to the first extension direction or tilts towards the first extension direction at an angle, so that the third bracket can swing with respect to the display surface.

7. The functional assembly according to claim 6, wherein the base is a charging dock, the charging dock comprises a wireless charging pad pivotally connected to the one side of the third bracket and rotatable with respect to the third rotation shaft, and the third rotation shaft is parallel to the display surface of the display device, so that the wireless charging pad can swing with respect to the display surface.

8. The functional assembly according to claim 7, wherein the charging dock further comprises a clamping device disposed on two sides of the wireless charging pad and used to clamp a wireless electronic device disposed on the wireless charging pad.

9. The functional assembly according to claim 6, wherein the third bracket has a third shaft hole and a third limiting structure, the third rotation shaft is disposed in the third shaft hole, the third rotation shaft and the third shaft hole are tightly engaged, and a rotation angle of the third rotation shaft is limited by the third limiting structure to be less than or equivalent to a pre-determined angle.

10. The functional assembly according to claim 1, further comprising a charging wire, wherein one end of the charging wire is fixed to the base, another end of the charging wire is fixed and connected to the display device, the charging wire has a winding portion adapted to be stretched or contracted when the base rotates with respect to the first rotation shaft and the second rotation shaft.

11. A multi-functional display device, comprising:
a display device having a display surface; and
an assembly comprising:
a first bracket disposed on a back surface of the display device, wherein the first bracket is extended from one side of the display device towards a first extension direction, and one end of the first bracket has a first rotation shaft;
a second bracket pivotally connected to the one end of the first bracket and rotatable with respect to the first rotation shaft, wherein one end of the second bracket has a second rotation shaft, one of the first rotation shaft and the second rotation shaft is perpendicular to the display surface of the display device, and the other one of the first rotation shaft and the second rotation shaft is parallel to the display surface of the display device; and
a base pivotally connected to the one end of the second bracket is rotatable with respect to the second rotation shaft, wherein the base is adapted to be shielded from the back surface of the display device, when the base is exposed on the one side of the display device, a placing surface of the base and the display surface both face a front surface of the display device.

12. The multi-functional display device according to claim 11, wherein the first bracket is fixed on the back surface of the display device or is slidably disposed on the back surface of the display device.

13. The multi-functional display device according to claim 11, wherein the back surface of the display device has a slot facing the one side of the display device, and the first bracket is pluggably installed in the slot.

14. The multi-functional display device according to claim 11, wherein the first bracket has a first shaft hole and a first limiting structure, the first rotation shaft is disposed in the first shaft hole, the first rotation shaft and the first shaft hole are tightly engaged and a rotation angle of the first rotation shaft is limited by the first limiting structure to be less than or equivalent to a pre-determined angle.

15. The multi-functional display device according to claim 11, wherein the second bracket has a second shaft hole and a second limiting structure, the second rotation shaft is disposed in the second shaft hole, the second rotation shaft and the second shaft hole are tightly engaged and a rotation angle of the second rotation shaft is limited by the second limiting structure to be less than or equivalent to a pre-determined angle.

16. The multi-functional display device according to claim 11, wherein the base has a third bracket, one side of the third bracket has a third rotation shaft extended from the one end of the second bracket towards a second extension direction, and the second extension direction is parallel to the first extension direction or tilts towards the first extension direction at an angle, so that the third bracket can swing with respect to the display surface.

17. The multi-functional display device according to claim 16, wherein the base is a charging dock, the charging dock comprises a wireless charging pad pivotally connected to the one side of the third bracket and rotatable with respect to the third rotation shaft, and the third rotation shaft is parallel to the display surface of the display device, so that the wireless charging pad can swing with respect to the display surface.

18. The multi-functional display device according to claim 17, wherein the charging dock further comprises a clamping device disposed on two sides of the wireless charging pad and used to clamp a wireless electronic device disposed on the wireless charging pad.

19. The multi-functional display device according to claim 16, wherein the third bracket has a third shaft hole and a third limiting structure, the third rotation shaft is disposed in the third shaft hole, the third rotation shaft and the third shaft hole are tightly engaged, and a rotation angle of the third rotation shaft is limited by the third limiting structure to be less than or equivalent to a pre-determined angle.

20. The multi-functional display device according to claim 11, further comprising a charging wire, wherein one end of the charging wire is fixed to the base, another end of the charging wire is fixed and connected to the display device, the charging wire has a winding portion adapted to be stretched or contracted when the base rotates with respect to the first rotation shaft and the second rotation shaft.
